(19) United States
(12) Patent Application Publication
(10) Pub. No.: US 2025/0251292 A1
(43) Pub. Date: Aug. 7, 2025

(54) TEMPERATURE ESTIMATION SYSTEM AND TEMPERATURE ESTIMATION METHOD

(71) Applicant: HONDA MOTOR CO., LTD., Tokyo (JP)

(72) Inventor: Ryota KITAMOTO, Saitama (JP)

(21) Appl. No.: 19/013,403

(22) Filed: Jan. 8, 2025

(30) Foreign Application Priority Data
Feb. 6, 2024 (JP) 2024-016688

(51) Int. Cl. G01K 7/42; H02M 1/00; H02M 1/14; H02M 1/32

(52) U.S. Cl. CPC G01K 7/425; H02M 1/0009; H02M 1/14; H02M 1/327

(57) ABSTRACT

A temperature estimation system includes: an electrical device provided with multiple first monitoring targets each composed of one or more electronic components, multiple temperature sensors each detecting a temperature of a corresponding one of the first monitoring targets, and multiple second monitoring targets each composed of one or more electronic components; a cooling device having a cooling path in which a coolant for cooling the multiple first monitoring targets and the multiple second monitoring targets flows; and a processor configured to estimate temperatures of the multiple second monitoring targets based on the temperatures of the first monitoring targets detected by the temperature sensors, wherein the processor estimates the temperature of each of the second monitoring targets based on the temperature of one of the first monitoring targets that is adjacent thereto in the cooling path.

### TECHNICAL FIELD

The present invention relates to a temperature estimation system for estimating the temperature of a monitoring target in an electrical device and a temperature estimation method in the temperature estimation system.

### BACKGROUND ART

In recent years, efforts to realize a low-carbon society or a carbon-neutral society are becoming more active, and in relation to vehicles, research and development on electrification technology are being conducted to reduce CO2 emission and to improve energy efficiency. To stabilize the operation of a system provided with an electronic component to be mounted on an electric vehicle and to suppress increase in cost, it is important to monitor the temperature of the electronic component with a small number of components and to prevent overheating of the electronic component.

For example, JP2023-160416A discloses a temperature estimation system that estimates, based on the temperature of a first monitoring target detected by the temperature sensor, the temperature of a second monitoring target which is different from the first monitoring target. This temperature estimation system is provided with a cooling device having a cooling path in which a coolant for cooling the first monitoring target and the second monitoring target flows and a temperature sensor for detecting the temperature of the first monitoring target. The controller of the temperature estimation system derives an amount of heat transferred from the first monitoring target to the cooling path based on a first temperature estimate, which is a temperature estimate of the first monitoring target when it is assumed that the amount of heat transferred from the first monitoring target to the cooling path is zero, and the temperature of the first monitoring target, and estimates a second temperature estimate, which is a temperature estimate of the second monitoring target, based on the amount of heat transferred from the first monitoring target to the cooling path and an amount of heat generation according to the current operation state of the second monitoring target.

However, with the aforementioned conventional technology, when there are at least two heat generating electrical components that are to be cooled by the coolant flow path and there are multiple second monitoring targets for which temperature sensors are not provided, it is not possible to estimate the temperatures of the multiple second monitoring targets.

### SUMMARY OF THE INVENTION

In view of the foregoing background, a primary object of the present invention is to make it possible to estimate the temperatures of multiple second monitoring targets for which temperature sensors are not provided.

To achieve the above object, one aspect of the present invention provides a temperature estimation system (1), comprising: an electrical device (10) provided with multiple first monitoring targets (12U, 12V, 12W) each composed of one or more electronic components, multiple temperature sensors (14) each detecting a temperature of a corresponding one of the first monitoring targets, and multiple second monitoring targets (11, 13) each composed of one or more electronic components; a cooling device (30) having a cooling path (31) in which a coolant for cooling the multiple first monitoring targets and the multiple second monitoring targets flows; and a processor (20) configured to estimate temperatures of the multiple second monitoring targets based on the temperatures of the first monitoring targets detected by the temperature sensors, wherein the processor estimates the temperature of each of the second monitoring targets based on the temperature of one of the first monitoring targets that is adjacent thereto in the cooling path.

According to this aspect, the temperature of each of the second monitoring targets can be estimated based on the temperature of one of the first monitoring targets that is adjacent thereto in the cooling path among the multiple first monitoring targets whose temperatures are detected by the multiple temperature sensors. Also, by estimating the temperature of each second monitoring target based on the temperature of one of the first monitoring targets that is adjacent thereto in the cooling path, it is possible to accurately estimate the temperature of each second monitoring target.

In the above aspect, preferably, the multiple second monitoring targets include an upstream-side second monitoring target (13) which is disposed on an upstream side of the multiple first monitoring targets in the cooling path and a downstream-side second monitoring target (11) which is disposed on a downstream side of the multiple first monitoring targets in the cooling path, and the processor estimates a temperature of the upstream-side second monitoring target based on the temperature of one (12U) of the multiple first monitoring targets that is disposed on a most upstream side in the cooling path and estimates a temperature of the downstream-side second monitoring target based on the temperature of one (12W) of the multiple first monitoring targets that is disposed on a most downstream side in the cooling path.

According to this aspect, the temperature of the upstream-side second monitoring target can be accurately estimated based on the temperature of the first monitoring target positioned immediately downstream thereof, and the temperature of the downstream-side second monitoring target can be accurately estimated based on the temperature of the first monitoring target positioned immediately upstream thereof.

In the above aspect, preferably, the electrical device is an electric power converter (10), each of the first monitoring targets is a power module (12U, 12V, 12W) of an IPM, and the second monitoring targets include a capacitor (13) and a reactor (11).

According to this aspect, the temperature of the capacitor and the temperature of the reactor can be estimated by using the detection values of the multiple temperature sensors that detect the temperatures of the power modules of the IPM.

To achieve the above object, another aspect of the present invention provides a temperature estimation method in a temperature estimation system (1), the temperature estimation system comprising: an electrical device (10) provided with multiple first monitoring targets (12U, 12V, 12W) each composed of one or more electronic components, multiple temperature sensors (14) each detecting a temperature of a corresponding one of the first monitoring targets, and multiple second monitoring targets (11, 13) each composed of one or more electronic components; a cooling device (30) having a cooling path (31) in which a coolant for cooling the multiple first monitoring targets and the multiple second monitoring targets flows; and a processor (20) configured to estimate temperatures of the multiple second monitoring targets based on the temperatures of the first monitoring targets detected by the temperature sensors, wherein the processor estimates a temperature of each of the second monitoring targets based on the temperature of one of the first monitoring targets that is adjacent thereto in the cooling path.

According to this aspect, the processor can estimate the temperature of each of the second monitoring targets based on the temperature of one of the first monitoring targets that is adjacent thereto in the cooling path among the multiple first monitoring targets whose temperatures are detected by the multiple temperature sensors. Also, by estimating the temperature of each second monitoring target based on the temperature of one of the first monitoring targets that is adjacent thereto in the cooling path, the processor can accurately estimate the temperature of each second monitoring target.

In the above aspect, preferably, the multiple second monitoring targets include an upstream-side second monitoring target (13) which is disposed on an upstream side of the multiple first monitoring targets in the cooling path and a downstream-side second monitoring target (11) which is disposed on a downstream side of the multiple first monitoring targets in the cooling path, and the processor estimates a temperature of the upstream-side second monitoring target based on the temperature of one (12U) of the multiple first monitoring targets that is disposed on a most upstream side in the cooling path and estimates a temperature of the downstream-side second monitoring target based on the temperature of one (12W) of the multiple first monitoring targets that is disposed on a most downstream side in the cooling path.

According to this aspect, the temperature of the upstream-side second monitoring target can be accurately estimated based on the temperature of the first monitoring target positioned immediately downstream thereof, and the temperature of the downstream-side second monitoring target can be accurately estimated based on the temperature of the first monitoring target positioned immediately upstream thereof.

According to the above aspect, it becomes possible to estimate the temperatures of multiple second monitoring targets for which temperature sensors are not provided.

### BRIEF DESCRIPTION OF THE DRAWINGS

FIG. 1 is a diagram showing one example of a schematic configuration of a temperature estimation system according to an embodiment of the present invention;

FIG. 2 is a diagram showing one example of a schematic configuration of a cooling system of the temperature estimation system; and

FIG. 3 is a block diagram of a temperature estimation function of the temperature estimation system.

### DETAILED DESCRIPTION OF THE INVENTION

In the following, an embodiment of the present invention will be described in detail with reference to the drawings.

### <Temperature Estimation System >

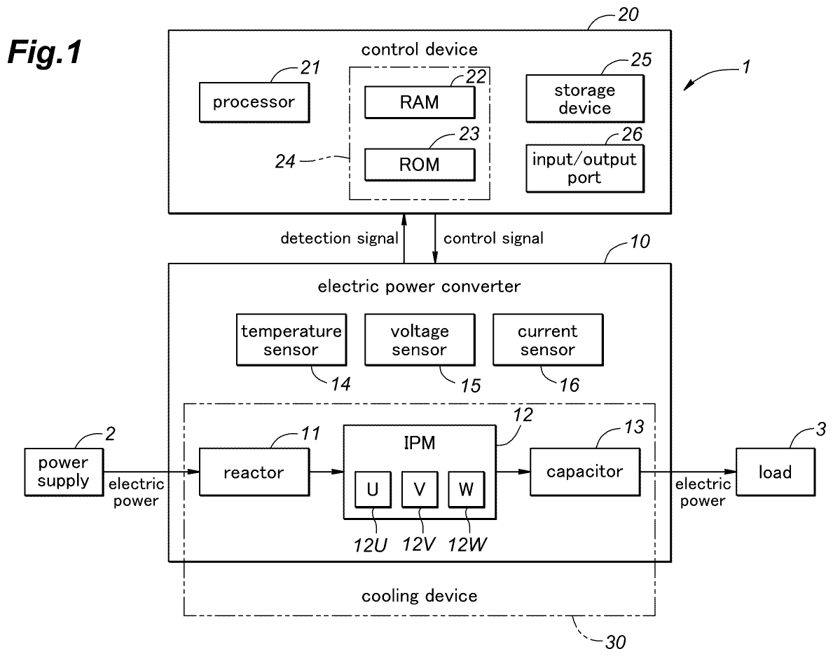

FIG. 1 is a diagram showing one example of a schematic configuration of a temperature estimation system 1 according to the embodiment. The temperature estimation system 1 is a system for making it possible to estimate, based on the temperatures of multiple first monitoring targets detected by multiple temperature sensors 14 (shown by a single block in FIG. 1) of an electrical device, the temperatures of multiple second monitoring targets that are different from the first monitoring targets. Accordingly, without providing multiple temperature sensors 14 for detecting the temperatures of the second monitoring targets, it is possible to acquire the temperatures of the multiple second monitoring targets, thereby simplifying the configuration.

Each of the first monitoring targets and the second monitoring targets is an article that is composed of one or more electronic components and generates heat when in operation (in other words, when supplied with electric power). In the present embodiment, the first monitoring targets are power modules of an intelligent power module (IPM) 12. A reactor 11 connected to an input side of the IPM 12 is a downstream-side second monitoring target, and a capacitor 13 connected to an output side of the IPM 12 is an upstream-side second monitoring target. Note, however, that the articles which can be the first monitoring targets and the second monitoring targets are not particularly limited. In the present embodiment, the electrical device is an electric power converter 10. Note, however, that the electrical device is not particularly limited, and may be an electric device driven by electricity or an electric control device.

As shown in FIG. 1, the temperature estimation system 1 of the present embodiment is configured to include an electric power converter 10 electrically connected to each of a power supply 2 and a load 3, a controller 20 configured to perform overall control of the electric power converter 10, and a cooling device 30 for cooling the electric power converter 10. In the present embodiment, the temperature estimation system 1 is installed in an electric vehicle, such as an electric car or a hybrid electric car, provided with a motor as a drive source. In the following, the electric vehicle in which the temperature estimation system 1 is installed is simply referred to as “the vehicle.”

The power supply 2 is a voltage/current source configured to be capable of outputting predetermined electric power to the electric power converter 10 and may be, for example, a battery serving as an electric storage unit mounted on the vehicle. More specifically, the power supply 2 may be a high-voltage battery (a so-called driving battery) that is configured by connecting multiple electric storage cells, which are realized by lithium ion batteries, nickel hydrogen batteries, or the like, in series or in series-parallel, and can output a high voltage of 100 to 200 [V]. However, the power supply 2 is not limited to such a high-voltage battery and may be, for example, a low-voltage battery (a so-called auxiliary battery) capable of outputting a low voltage of about 12 [V], a fuel cell, an electric generator, etc.

The load 3 is electric equipment that operates with electric power supplied from the electric power converter 10 and may be, for example, a motor serving as a drive source of the vehicle (hereinafter may be referred to as “the drive motor”). However, the load 3 is not limited to such a drive motor and may be, for example, a motor for driving a fan, a fuel pump, a compressor, or the like installed in the vehicle (for example, a motor for an air conditioner).

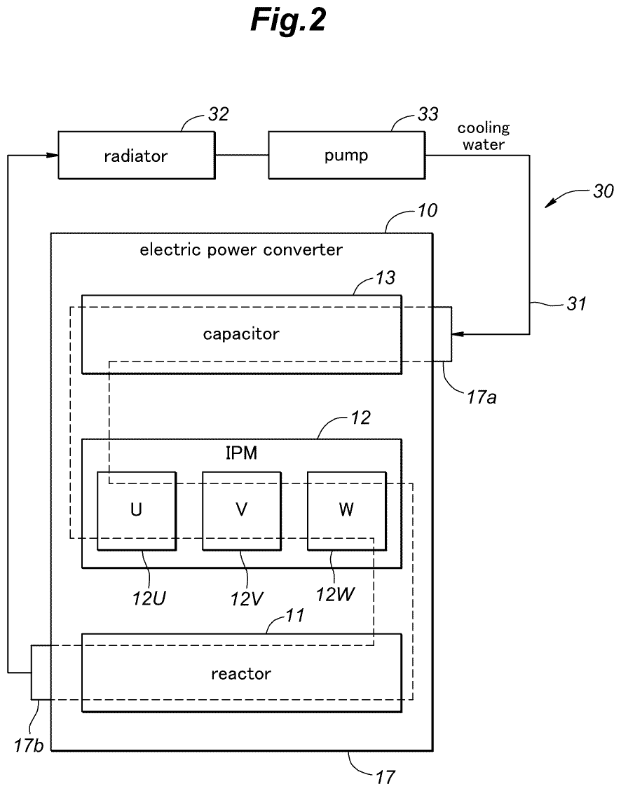

The electric power converter 10 is a device that, under the control of the controller 20, converts the electric power supplied from the power supply 2 to predetermined electric power and outputs the converted electric power to the load 3. Specifically, the electric power converter 10 is configured to include the reactor 11 which is an example of the second monitoring target, the IPM 12 having power modules which are an example of the first monitoring targets, the capacitor 13 which is an example of the second monitoring target, the temperature sensors 14, a voltage sensor 15, and a current sensor 16. For example, the electric power converter 10 is configured such that the reactor 11, the IPM 12, the capacitor 13, the temperature sensors 14, the voltage sensor 15, and the current sensor 16 are contained in the same housing 17 (see FIG. 2).

The IPM 12 includes multiple power modules each composed of one or more electronic components such as switching elements which may be MOSFETs (Metal-Oxide-Semiconductor Field-Effect Transistors), IGBTs (Insulated Gate Bipolar Transistors), or the like. The IPM 12 converts the input electric power to predetermined electric power by switching these multiple switching elements under the control of the controller 20, and outputs the converted electric power. In this embodiment, the IPM 12 converts the DC electric current flowing from the power supply 2 toward the load 3 to AC electric current and converts the AC electric current flowing from the load 3 toward the power supply 2 to DC electric current.

The reactor 11 is electrically connected to each of a positive electrode terminal of the power supply 2 and the IPM 12. The reactor 11 controls and stabilizes the flow of DC electric current from the power supply 2 to the IPM 12. Also, the reactor 11 smooths the electric current flowing from the IPM 12 to the power supply 2.

The capacitor 13 is connected to the output side of the IPM 12 (more specifically, between the IPM 12 and the load 3) and functions as a DC-cut capacitor that cuts a DC component from the electric power outputted from the IPM 12.

Each temperature sensor 14 is a sensor configured to detect the temperature of a part of the IPM 12 and outputs a detection signal indicating the detected temperature to the controller 20. The voltage sensor 15 is a sensor for detecting the voltage of the electric power outputted from the IPM 12 (hereinafter may be also referred to as “the output voltage”) and outputting a detection signal indicating the detected output voltage to the controller 20. The current sensor 16 is a sensor for detecting the electric current of the electric power outputted of the IPM 12 and outputting a detection signal indicating the detected output electric current to the controller 20.

The controller 20 is configured by a computer including a processor 21 composed of a central processing unit (CPU) or the like, a memory 24 such as a RAM 22 and a ROM 23, a storage device 25 such as an HDD and an SSD, an input/output port 26, etc. The controller 20 is realized by an electronic control unit (ECU) and performs overall control of the entirety of the temperature estimation system 1. Note that the controller 20 may be realized by a single ECU or may be realized by multiple ECUs that operate cooperatively with each other.

During power travel of the vehicle, the controller 20 outputs a predetermined control signal to the electric power converter 10 as appropriate to control the electric power supplied from the power supply 2 to the load 3. Thereby, the load 3 functions as a drive motor and the vehicle travels. When the traveling vehicle is braked, the controller 20 outputs a predetermined control signal to the electric power converter 10 as appropriate to control the electric power supplied from the load 3 to the power supply 2. Thereby, the load 3 functions as an electric generator, and the regenerative electric power is charged to the power supply 2.

When the reactor 11, the IPM 12, and the capacitor 13 of the electric power converter 10 operate (in other words, when electric power is supplied to them) under the control of the controller 20, they generate heat. Of these, the temperature of the IPM 12 can become the highest. The cooling device 30 is a device for cooling the reactor 11, the IPM 12, and the capacitor 13 of the electric power converter 10.

FIG. 2 is a diagram showing one example of a schematic configuration of the cooling system of the temperature estimation system 1 according to the embodiment. The cooling device 30 has a cooling path 31 in which a coolant (for example, cooling water which may be called “LLC”) for cooling the reactor 11, the IPM 12, and the capacitor 13 flows. Also, the cooling device 30 includes a radiator 32 serving as a heat dissipation device for dissipating heat of the coolant flowing in the cooling path 31 to the outside air, and a pump 33 for circulating the coolant within the cooling device 30.

The reactor 11, the IPM 12, and the capacitor 13 are arranged on the cooling path 31 of the cooling device 30 so as to be capable of exchanging heat with the coolant flowing in the cooling path 31. The cooling path 31 is only required to be capable of exchanging heat with the heat generating electronic components of the electric power converter 10 and, in the present embodiment, is formed inside the housing 17 of the electric power converter 10. In another example, the cooling path 31 may be formed by a passage forming member that is a separate body from the housing 17. The heat from the reactor 11, the IPM 12, and the capacitor 13 is transferred to the coolant flowing in the cooling path 31 and thereafter is dissipated from the radiator 32 to the outside air. Thereby, the reactor 11, the IPM 12, and the capacitor 13 which can generate heat are cooled by the cooling device 30, and the temperature rise of them can be suppressed.

The housing 17 of the electric power converter 10 is formed with a cooling water inlet 17a and a cooling water outlet 17b. A part of the cooling path 31 from the cooling water inlet 17a to the cooling water outlet 17b of the housing 17 is formed as a single route. In the housing 17 of the electric power converter 10, the capacitor 13, the IPM 12 and the reactor 11 are arranged in this order from the upstream side to the downstream side of the cooling path 31.

To generate three-phase AC electric power, the IPM 12 includes switching elements constituting three power modules corresponding to the U phase, V phase, and W phase (hereinafter referred to as a U-phase power module 12U, a V-phase power module 12V, and a W-phase power module 12W). These three power modules are arranged along the cooling path 31. In the present embodiment, the U-phase power module 12U, the V-phase power module 12V, and the W-phase power module 12W are arranged in this order from the upstream side to the downstream side of the cooling path 31.

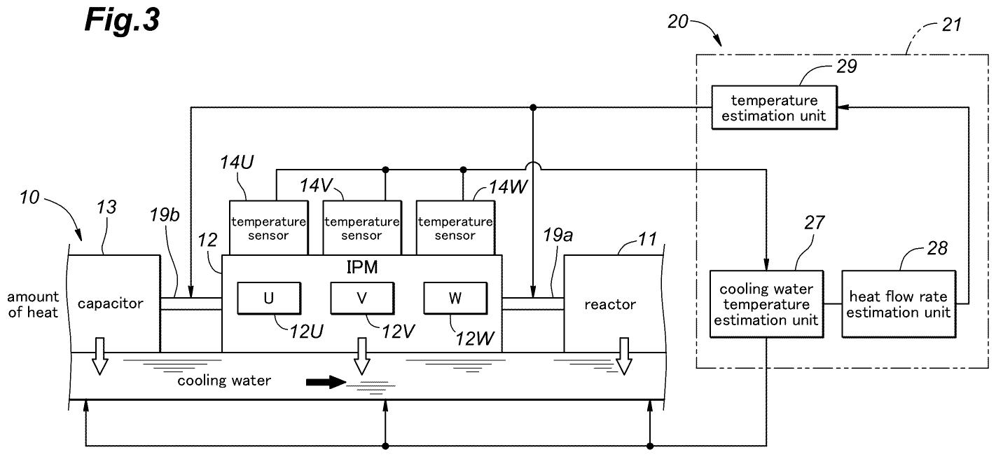

FIG. 3 is a block diagram of a temperature estimation function of the temperature estimation system 1 according to the embodiment. On the cooling path 31, the capacitor 13, the U-phase power module 12U, the V-phase power module 12V, the W-phase power module 12W, and the reactor 11 are arranged in this order from the upstream side to the downstream side. The temperature sensors 14 for detecting the temperatures of parts of the IPM 12 include a temperature sensor 14U for detecting the temperature of the U-phase power module 12U, a temperature sensor 14V for detecting the temperature of the V-phase power module 12V, and a temperature sensor 14W for detecting the temperature of the W-phase power module 12W. Each temperature sensor 14 is an element temperature sensor mounted on a semiconductor substrate for the corresponding power module and may be a thermistor, for example.

The reactor 11 and the IPM 12 are connected electrically and thermally via a first bus bar 19a configured by using a copper plate or the like. Similarly, the IPM 12 and the capacitor 13 are connected electrically and thermally via a second bus bar 19b configured by using a copper plate or the like. The reactor 11 and the capacitor 13 also may generate heat, but no dedicated sensors for detecting the temperatures of them are provided.

Therefore, the controller 20 of the present embodiment includes, as functional units realized by processing executed by the processor 21, a cooling water temperature estimation unit 27, a heat flow rate estimation unit 28, and a temperature estimation unit 29. The processor 21 is configured to estimate the temperatures of the capacitor 13 and the reactor 11 based on the temperatures detected by the multiple temperature sensors 14 provided in the IPM 12. Thereby, it is possible to estimate the temperatures of the capacitor 13 and the reactor 11 which are multiple second monitoring targets for which no dedicated temperature sensors are provided. In the following, a concrete temperature estimation method will be described.

### <Temperature Estimation Method>

When the temperature estimation system 1 is activated upon turning on of the ignition power supply or the accessory power supply of the vehicle, for example, the processor 21 estimates the temperature of the capacitor 13 according to the below-described estimation method at predetermined timings during the activation (for example, at a predetermined cycle).

First, the processor 21 derives a heat flow rate Q′ from the IPM 12 to the cooling water in the cooling path 31. The heat flow rate Q′ can be derived from the following formula (1), for example.

$${Q}^{′} = \frac{{T}_{IPM} - {T}_{w}}{R} \qquad ( 1 )$$

Here, T_{IPM} is the temperature of the IPM 12, T_{w} is a cooling water temperature, and R is a thermal resistance.

In the above formula (1), the cooling water temperature T_{w} is estimated from the temperature of the IPM 12 by the cooling water temperature estimation unit 27. In the present embodiment, a cooling water temperature estimation map for deriving the cooling water temperature T_{w} is pre-stored in the storage device 25, and the cooling water temperature estimation unit 27 estimates the cooling water temperature T_{w} by referring to this cooling water temperature estimation map.

Then, the heat flow rate estimation unit 28 of the controller 20 derives the heat flow rate Q′ from the IPM 12 to the cooling water in the cooling path 31 by calculating the above formula (1).

Subsequently, the temperature estimation unit 29 of the controller 20 calculates a heat flow rate from the IPM 12 to the second monitoring target (the reactor 11 or the capacitor 13) via the first bus bar 19a or the second bus bar 19b. Then, the temperature estimation unit 29 calculates an estimated temperature ti of the second monitoring target (the reactor 11 or the capacitor 13). The estimated temperature ti of the reactor 11 or the capacitor 13 can be derived from the following formula (2), for example.

$${t}_{i} = \frac{\frac{{T}_{H} - {T}_{L}}{kR} + kQ - {kQ}^{′}}{kC} \times t \qquad ( 2 )$$

Here, tᵢ is an estimated temperature of the second monitoring target, T_{H} is a temperature of the high temperature-side electronic component, T_{L} is a temperature of the low temperature-side electronic component, k is a coefficient, Q is an amount of heat, and t is time.

In the numerator on the right side of the above formula (2), the first term represents an inflow heat amount, the second term represents a heat generation loss, and the third term represents the amount of heat flowing to the cooling path 31. The high temperature-side electronic component is the IPM 12, and the low temperature-side electronic component is the reactor 11 or the capacitor 13. As the temperature T_{L} of the low temperature-side electronic component, for example, the most recently derived value (namely, previous value) of the temperature T_{L} of the low temperature-side electronic component derived recently may be used. When there is no most recently derived value, an initial value stored in the storage device 25 may be used.

When calculating the estimated temperature tᵢ of the capacitor 13 by using the above formula (2), the processor 21 uses, as the temperature T_{IPM} of the IPM 12 and the temperature T_{H} of the high temperature-side electronic component, the temperature of the U-phase power module 12U which is adjacent to the capacitor 13 in the cooling path 31, and uses, as the temperature T_{L} of the low temperature-side electronic component, the previous value or the initial value of the estimated temperature tᵢ of the capacitor 13. On the other hand, when calculating the estimated temperature tᵢ of the reactor 11 by using the above formula (2), the processor 21 uses, as the temperature T_{IPM} of the IPM 12 and the temperature T_{H} of the high temperature-side electronic component, the temperature of the W-phase power module 12W which is adjacent to the reactor 11 in the cooling path 31, and uses, as the temperature T_{L} of the low temperature-side electronic component, the previous value or the initial value of the estimated temperature tᵢ of the reactor 11.

As described above, the temperature estimation system 1 is provided with the multiple temperature sensors 14 (14U, 14V, 14W) for detecting the temperatures of the multiple power modules which are the first monitoring targets. Therefore, the processor 21 can estimate the temperature of each of the reactor 11 and the capacitor 13 which are the second monitoring targets based on the temperature of the power module that is adjacent thereto in the cooling path 31. Also, by estimating the temperature of each second monitoring target based on the temperature of the first monitoring target that is adjacent thereto in the cooling path 31, the processor 21 can accurately estimate the temperature of each second monitoring target.

The processor 21 estimates the temperature of the capacitor 13 which is the upstream-side second monitoring target based on the temperature of the U-phase power module 12U which is disposed on the most upstream side in the cooling path 31 among the multiple power modules. Further, the processor 21 estimates the temperature of the reactor 11 which is the downstream-side second monitoring target based on the temperature of the W-phase power module 12W which is disposed on the most downstream side in the cooling path 31 among the multiple power modules. Thereby, the processor 21 can accurately estimate the temperature of the capacitor 13 and the temperature of the reactor 11.

The processor 21 can estimate the temperature of the capacitor 13 and the temperature of the reactor 11 by using the detection values of the multiple temperature sensors 14 (14U, 14V, 14W) provided to detect the temperatures of the power modules of the IPM 12. Therefore, no dedicated sensors for detecting the temperature of the capacitor 13 and the temperature of the reactor 11 are necessary, and the number of components and the cost can be reduced, and the system configuration can be simplified.

Concrete embodiments have been described in the foregoing, but the present invention can be modified in various ways without being limited to the above embodiments or modifications. For example, the first monitoring targets and the second monitoring targets are not limited to the above embodiment. In the above embodiment, the temperature of one first monitoring target is used when estimating the temperature of each second monitoring target, but the temperature of two first monitoring targets may be used. Besides, the concrete structure, arrangement, number, material, or the like of each member or part may be appropriately changed without departing from the spirit of the present invention. Also, not all of the components shown in the foregoing embodiments are necessarily indispensable and they may be selectively adopted as appropriate.

1. A temperature estimation system, comprising:
an electrical device provided with multiple first monitoring targets each composed of one or more electronic components, multiple temperature sensors each detecting a temperature of a corresponding one of the first monitoring targets, and multiple second monitoring targets each composed of one or more electronic components;
a cooling device having a cooling path in which a coolant for cooling the multiple first monitoring targets and the multiple second monitoring targets flows; and
a processor configured to estimate temperatures of the multiple second monitoring targets based on the temperatures of the first monitoring targets detected by the temperature sensors,
wherein the processor estimates the temperature of each of the second monitoring targets based on the temperature of one of the first monitoring targets that is adjacent thereto in the cooling path.

2. The temperature estimation system according to claim 1, wherein the multiple second monitoring targets include an upstream-side second monitoring target which is disposed on an upstream side of the multiple first monitoring targets in the cooling path and a downstream-side second monitoring target which is disposed on a downstream side of the multiple first monitoring targets in the cooling path, and
the processor estimates a temperature of the upstream-side second monitoring target based on the temperature of one of the multiple first monitoring targets that is disposed on a most upstream side in the cooling path and estimates a temperature of the downstream-side second monitoring target based on the temperature of one of the multiple first monitoring targets that is disposed on a most downstream side in the cooling path.

3. The temperature estimation system according to claim 1, wherein the electrical device is an electric power converter, each of the first monitoring targets is a power module of an IPM, and the second monitoring targets include a capacitor and a reactor.

4. A temperature estimation method in a temperature estimation system, the temperature estimation system comprising:
an electrical device provided with multiple first monitoring targets each composed of one or more electronic components, multiple temperature sensors each detecting a temperature of a corresponding one of the first monitoring targets, and multiple second monitoring targets each composed of one or more electronic components;
a cooling device having a cooling path in which a coolant for cooling the multiple first monitoring targets and the multiple second monitoring targets flows; and
a processor configured to estimate temperatures of the multiple second monitoring targets based on the temperatures of the first monitoring targets detected by the temperature sensors,
wherein the processor estimates a temperature of each of the second monitoring targets based on the temperature of one of the first monitoring targets that is adjacent thereto in the cooling path.

5. The temperature estimation method according to claim 4, wherein the multiple second monitoring targets include an upstream-side second monitoring target which is disposed on an upstream side of the multiple first monitoring targets in the cooling path and a downstream-side second monitoring target which is disposed on a downstream side of the multiple first monitoring targets in the cooling path, and
the processor estimates a temperature of the upstream-side second monitoring target based on the temperature of one of the multiple first monitoring targets that is disposed on a most upstream side in the cooling path and estimates a temperature of the downstream-side second monitoring target based on the temperature of one of the multiple first monitoring targets that is disposed on a most downstream side in the cooling path.
